(19) United States
(12) Patent Application Publication
(10) Pub. No.: US 2026/0130293 A1
(43) Pub. Date: May 7, 2026

(54) SEMICONDUCTOR PACKAGE

(71) Applicant: Samsung Electronics Co., Ltd., Suwon-si (KR)

(72) Inventors: DONGKUK LEE, Suwon-si (KR); SEUNGDUK BAEK, Suwon-si (KR)

(21) Appl. No.: 19/246,569

(22) Filed: Jun. 23, 2025

(30) Foreign Application Priority Data
Nov. 6, 2024 (KR) 10-2024-0156362

(51) Int. Cl. H01L 23/498; H01L 23/00; H01L 23/31; H01L 23/538; H01L 25/065

(52) U.S. Cl. CPC H10W 90/701; H10W 70/611; H10W 90/00; H10W 90/401; H10W 74/117; H10W 74/15; H10W 90/724; H10W 90/734

(57) ABSTRACT

A semiconductor package includes an interposer chip on a package substrate, a first semiconductor chip on the interposer chip, and a second semiconductor chip on the interposer chip and horizontally spaced apart from the first semiconductor chip. The interposer chip is on the package substrate through first and second connection terminals. The first semiconductor chip is on the interposer chip through third connection terminals. The second semiconductor chip is on the interposer chip through fourth connection terminals. A width of the first connection terminals is the same as that of the third connection terminals. An interval between the first connection terminals is the same as that between the third connection terminals. A width of the second connection terminals is the same as that of the fourth connection terminals. An interval between the second connection terminals is the same as that between the fourth connection terminals.

### CROSS-REFERENCE TO RELATED APPLICATION

This application claims priority under 35 U.S.C § 119 to Korean Patent Application No. 10-2024-0156362 filed on Nov. 6, 2024 in the Korean Intellectual Property Office, the entirety of which is hereby incorporated by reference.

### BACKGROUND

With the development of electronic industry, electronic products have increasingly demands for high performance, high speed, and compact size. To meet the trend, there has recently been developed a packaging technology in which a plurality of semiconductor chips are mounted in a single package.

Portable devices have been increasingly demanded in recent electronic product markets, and as a result, it has been ceaselessly required for reduction in size and weight of electronic parts mounted on the portable devices. In order to accomplish the reduction in size and weight of the electronic parts, there is need for technology to integrate a number of individual devices into a single package as well as technology to reduce individual sizes of mounting parts. Various problems occur in association with an increase in stacking number of devices.

### SUMMARY

Some aspects of the present disclosure provide semiconductor packages with improved structural stability.

Some aspects of the present disclosure provide semiconductor packages with improved electrical properties.

According to some implementations of the present disclosure, a semiconductor package may comprise: a package substrate; an interposer chip on the package substrate; a first semiconductor chip mounted on the interposer chip; and a second semiconductor chip mounted on the interposer chip and horizontally spaced apart from the first semiconductor chip. The interposer chip may be mounted on the package substrate through a plurality of first connection terminals and a plurality of second connection terminals, the first and second connection terminals being on a bottom surface of the interposer chip. The first semiconductor chip may be mounted on the interposer chip through a plurality of third connection terminals on a bottom surface of the first semiconductor chip. The second semiconductor chip may be mounted on the interposer chip through a plurality of fourth connection terminals on a bottom surface of the second semiconductor chip. A first width of the first connection terminals may be the same as a third width of the third connection terminals. A first interval between the first connection terminals may be the same as third interval between the third connection terminals. A second width of the second connection terminals may be the same as a fourth width of the fourth connection terminals. A second interval between the second connection terminals may be the same as a fourth interval between the fourth connection terminals.

According to some implementations of the present disclosure, a semiconductor package may comprise: a package substrate; an interposer chip on the package substrate; a first semiconductor chip mounted on the interposer chip; a second semiconductor chip mounted on the interposer chip and horizontally spaced apart from the first semiconductor chip; a plurality of first connection terminals on a first region of a bottom surface of the interposer chip, the first connection terminals connecting the interposer chip and the package substrate to each other; a plurality of second connection terminals on a second region of the bottom surface of the interposer chip, the second connection terminals connecting the interposer chip and the package substrate to each other; a plurality of third connection terminals that connect the interposer chip and the first semiconductor chip to each other; and a plurality of fourth connection terminals that connect the interposer chip and the second semiconductor chip to each other. A first width of the first connection terminals may be the same as a third width of the third connection terminals. A second width of the second connection terminals may be the same as a fourth width of the fourth connection terminals. The first region may vertically overlap the first semiconductor chip. The second region may vertically overlap the second semiconductor chip.

According to some implementations of the present disclosure, a semiconductor package may comprise: a package substrate; an interposer chip mounted on the package substrate through a plurality of dummy terminals, a plurality of first connection terminals, and a plurality of second connection terminals; a semiconductor chip mounted on the interposer chip through the third connection terminals; and a chip stack mounted on the interposer chip through the fourth connection terminals. The first and third connection terminals may be electrically connected to the semiconductor chip. The second and fourth connection terminals may be electrically connected to the chip stack. A width of the first connection terminals may be the same as a width of the third connection terminals. A width of the second connection terminals may be the same as a width of the fourth connection terminals. Each of the third connection terminals may be positioned above one of the first connection terminals. Each of the fourth connection terminals may be positioned above one of the second connection terminals. The dummy terminals may be between the first connection terminals and the third connection terminals and may be electrically insulated from the semiconductor chip and the chip stack.

### BRIEF DESCRIPTION OF DRAWINGS

FIG. 1 is a cross-sectional view showing an example of a semiconductor package.

FIG. 2 is a plan view showing a top surface of an interposer chip depicted in FIG. 1.

FIG. 3 is a plan view showing a bottom surface of an interposer chip depicted in FIG. 1.

FIGS. 4 and 5 are cross-sectional views showing examples of semiconductor packages.

FIG. 6 is a plan view showing a top surface of an interposer chip depicted in FIG. 5.

FIG. 7 is a plan view showing a bottom surface of an interposer chip depicted in FIG. 5.

FIG. 8 is a cross-sectional view showing an example of a semiconductor package.

FIG. 9 is a plan view showing a top surface of an interposer chip depicted in FIG. 8.

FIG. 10 is a plan view showing a bottom surface of an interposer chip depicted in FIG. 8.

FIGS. 11 to 14 are cross-sectional views showing examples of semiconductor packages.

FIGS. 15 to 20 are cross-sectional views showing an example of a method of fabricating a semiconductor package.

### DETAILED DESCRIPTION

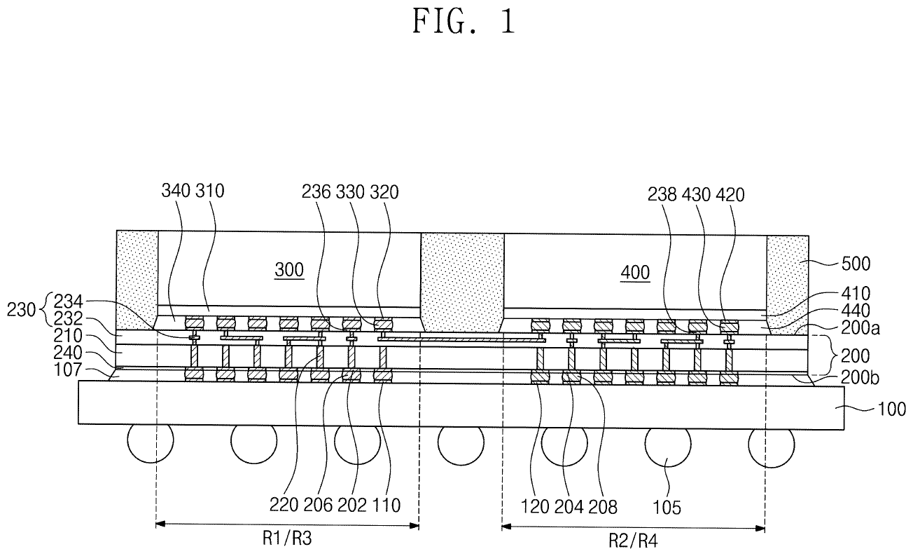

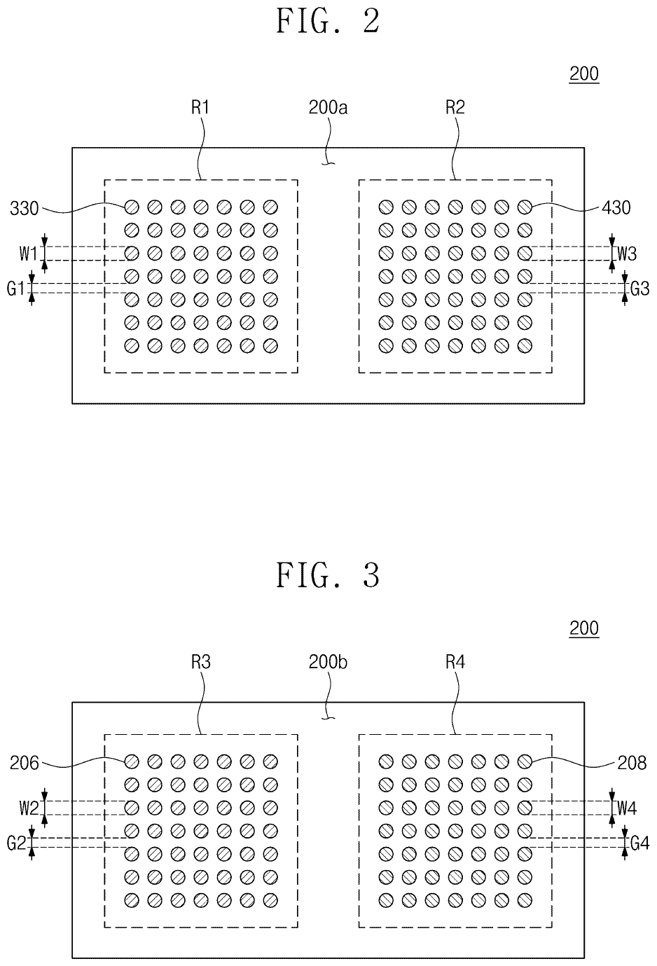

FIG. 1 is a cross-sectional view showing an example of a semiconductor package. FIG. 2 is a plan view showing a top surface of an interposer chip depicted in FIG. 1. FIG. 3 is a plan view showing a bottom surface of an interposer chip depicted in FIG. 1.

Referring to FIG. 1, a package substrate 100 may be provided. The package substrate 100 may include a printed circuit board (PCB) having a signal pattern on a top surface of the package substrate 100.

The package substrate 100 may include first substrate pads 110 and second substrate pads 120 provided on the top surface of the package substrate 100. The first substrate pads 110 may be pads electrically connected to a first semiconductor chip 300 which will be discussed below. The second substrate pads 120 may be pads electrically connected to a second semiconductor chip 400 which will be discussed below. On the top surface of the package substrate 100, a region where the first substrate pads 110 are provided may be spaced apart from a region where the second substrate pads 120 are provided. This configuration will be discussed in detail below with a description of an interposer chip 200.

A plurality of external terminals 105 may be disposed below the package substrate 100. The external terminals 105 may include solder balls or solder bumps, and based on type and arrangement of the external terminals 105, a semiconductor package may be provided in the form of one of a ball grid array (BGA) type, a fine ball-grid array (FBGA) Type, and a land grid array (LGA) type.

An interposer chip 200 may be provided on the package substrate 100. The interposer chip 200 may include a base layer 210, through vias 220, and a redistribution layer 230.

The base layer 210 may include a semiconductor substrate. The base layer 210 may include a semiconductor material. For example, the base layer 210 may be a silicon (Si) substrate.

The base layer 210 may be provided with the through vias 220 that penetrate the base layer 210. The through vias 220 may vertically penetrate the base layer 210 to be exposed on a top surface of the base layer 210 and a bottom surface of the base layer 210. The through vias 220 may include a metallic material, such as copper (Cu).

The redistribution layer 230 may be disposed on the top surface of the base layer 210. The redistribution layer 230 may cover the top surface of the base layer 210. The redistribution layer 230 may include a chip dielectric pattern 232 and chip wiring patterns 234.

The chip dielectric pattern 232 may cover the top surface of the base layer 210. The chip dielectric pattern 232 may include a photo-imageable dielectric (PID). For example, the photo-imageable dielectric may include at least one selected from photosensitive polyimide (PI), polybenzoxazole (PBO), phenolic polymers, and benzocyclobutene polymers. The chip dielectric pattern 232 may include a dielectric material. For example, the chip dielectric pattern 232 may include silicon oxide (SiO), silicon nitride (SiN), silicon oxynitride (SiON), silicon carbonitride (SiCN), or dielectric polymers. FIG. 1 depicts the chip dielectric pattern 232 as a single layer, but the chip dielectric pattern 232 is not limited thereto. The chip dielectric pattern 232 may be provided in the form of a multi-layered structure in which a plurality of dielectric layers are stacked.

The chip wiring patterns 234 may be provided in the chip dielectric pattern 232. The chip wiring patterns 234 may horizontally extend in the chip dielectric pattern 232. The chip wiring patterns 234 may be a configuration for redistribution of the redistribution layer 230. The chip wiring patterns 234 may include a conductive material. For example, the chip wiring patterns 234 may include copper (Cu) or aluminum (Al).

The chip wiring patterns 234 may have a damascene structure. For example, the chip wiring patterns 234 may each have a head part and a tail part that are connected into a single unitary piece. The head part and the tail part of the chip wiring pattern 234 may have a T-shaped cross-section.

The head part of the chip wiring pattern 234 may be a wiring portion for horizontally expanding a wiring line in the redistribution layer 230. The head part may horizontally extend in the chip dielectric pattern 232.

The tail part of the chip wiring pattern 234 may be a via portion for vertically connecting wiring lines in the redistribution layer 230. The tail part may be coupled to the head part of the chip wiring pattern 234 that overlies or underlies the tail part. The tail parts of lowermost ones of the chip wiring patterns 234 may penetrate the chip dielectric pattern 232 to be exposed on a bottom surface of the redistribution layer 230 or a bottom surface of the chip dielectric pattern 232. The tail parts of the lowermost chip wiring patterns 234 may be coupled to top surfaces of the through vias 220.

The redistribution layer 230 may include first upper pads 236 and second upper pads 238 provided on a top surface of the redistribution layer 230. FIG. 1 depicts that the first upper pads 236 and the second upper pads 238 protrude onto the top surface of the chip dielectric pattern 232, but the pad configuration is not limited thereto. The first upper pads 236 and the second upper pads 238 may be provided in the chip dielectric pattern 232, and may have their top surfaces coplanar with the top surface of the chip dielectric pattern 232. The chip wiring patterns 234 may electrically connect the first upper pads 236 and the second upper pads 238 to the through vias 220.

Referring together to FIGS. 1 and 2, a top surface 200a of the interposer chip 200 may have a first region R1 and a second region R2. The first region R1 and the second region R2 may be horizontally spaced apart from each other. The first region R1 may be an area where a first semiconductor chip 300 is mounted. The second region R2 may be an area where a second semiconductor chip 400 is mounted. The first upper pads 236 may be provided on the first region R1. For example, the first upper pads 236 may be pads of the interposer chip 200 that are provided for mounting the first semiconductor chip 300. The second upper pads 238 may be provided on the second region R2. For example, the second upper pads 238 may be pads of the interposer chip 200 that are provided for mounting the second semiconductor chip 400. The first upper pads 236 and the second upper pads 238 may include a metallic material, such as copper (Cu).

A width of the first upper pad 236 may be substantially the same as or similar to that of the second upper pad 238. A width can include, for example, a width, a diameter, a length, and/or another characteristic dimension. “Same,” as used herein, includes values that are the same within a process variation or process tolerance, as would be understood by one of ordinary skill in the relevant art.

Referring back to FIG. 1, first lower pads 202 and second lower pads 204 may be provided on a bottom surface 200b of the interposer chip 200. The first lower pads 202 and the second lower pads 204 may be provided on the bottom surface of the base layer 210. The through vias 220 may vertically penetrate the base layer 210 to be coupled to top surfaces of the first lower pads 202 and top surfaces of the second lower pads 204. The first lower pads 202 may be electrically connected to the first upper pads 236 by way of the through vias 220 and the chip wiring pattern 234. For example, the first lower pads 202 may be pads of the interposer chip 200 that are provided for signals transferred from or to the first semiconductor chip 300. The second lower pads 204 may be electrically connected to the second upper pads 238 by way of the through vias 220 and the chip wiring pattern 234. For example, the second lower pads 204 may be pads of the interposer chip 200 that are provided for signals transferred from or to the second semiconductor chip 400.

Referring together to FIGS. 1 and 3, the bottom surface 200b of the interposer chip 200 may have a third region R3 and a fourth region R4. The third region R3 and the fourth region R4 may be horizontally spaced apart from each other. The first lower pads 202 may be provided on the third region R3. The second lower pads 204 may be provided on the fourth region R4. The first lower pads 202 and the second lower pads 204 may include a metallic material, such as copper (Cu).

A width of the first lower pad 202 may be substantially the same as or similar to that of the second lower pad 204.

Referring again to FIG. 1, the width of the first upper pad 236 and the width of the first lower pad 202 may be substantially the same as or similar to each other. The width of the second upper pad 238 and the width of the second lower pad 204 may be substantially the same as or similar to each other. An interval between the first upper pads 236 may be substantially the same as or similar to that between the first lower pads 202. An interval between the second upper pads 238 may be substantially the same as or similar to that between the second lower pads 204. In this description, an interval between pads or an interval between terminals may refer to a distance between neighboring two pads or between neighboring two terminals when the pads or the terminals are arranged to have a specific pattern on one plane.

The first region R1 may vertically overlap the third region R3. The second region R2 may vertically overlap the fourth region R4.

The first upper pads 236 may be vertically aligned with the first lower pads 202. For example, each of the first upper pads 236 may be positioned on one of the first lower pads 202. In this sense, the first upper pads 236 may one-to-one correspond to the first lower pads 202, and a pair of first upper pads 236 may transceive the same electric signal with the first lower pad 202, where “transceive” means transmit and/or receive. A first upper pad 236 may transceive the same electric signal with its corresponding first lower pad 202. The scope of the present disclosure, however, is not limited thereto, and the pair of first upper pads 236 may transceive different electric signals with the first lower pad 202. A first upper pad 236 may transceive different electric signals with its corresponding first lower pad 202. The pair of first upper pads 236 may vertically overlap the first lower pad 202. A first upper pad 236 may vertically overlap its corresponding first lower pad 202.

The second upper pads 238 may be vertically aligned with the second lower pads 204. For example, each of the second upper pads 238 may be positioned on one of the second lower pads 204. In this sense, the second upper pads 238 may one-to-one correspond to the second lower pads 204, and a pair of second upper pads 238 may transceive the same electric signal with the second lower pad 204. A second upper pad 238 may transceive the same electric signal with its corresponding second lower pad 204. The scope of the present disclosure, however, is not limited thereto, and the pair of second upper pads 238 may transceive different electric signals with the second lower pad 204. A second upper pad 238 may transceive different electric signals with its corresponding second lower pad 204. The pair of second upper pads 238 may vertically overlap the second lower pad 204. A second upper pad 238 may vertically overlap its corresponding second lower pad 204.

The first upper pads 236 and the second upper pads 238 may have some upper pads that are not connected to the through vias 220, and those upper pads may be electrically connected through ones of the chip wiring patterns 234 of the redistribution layer 230. Those chip wiring patterns 234 may be wiring lines for electrical connection between the first semiconductor chip 300 and the second semiconductor chip 400. The connections, however, are not limited thereto. The first upper pads 236 may not be electrically connected to the second upper pads 238.

A passivation layer 240 may be provided on the bottom surface 200b of the interposer chip 200. The passivation layer 240 may cover the bottom surface of the base layer 210. The passivation layer 240 may surround the first lower pads 202 and the second lower pads 204. The first lower pads 202 and the second lower pads 204 may be exposed on a bottom surface of the passivation layer 240. The passivation layer 240 may be formed of a single or multiple layer including, for example, at least one selected from silicon oxide (SiO), silicon nitride (SiN), silicon oxynitride (SiON), and porous dielectrics. The passivation layer 240 may include a dielectric polymer, such as a photo-imageable dielectric.

The interposer chip 200 may be flip-chip mounted on the package substrate 100. For example, the interposer chip 200 may be mounted on the package substrate 100 through first substrate terminals 206 provided on the first lower pads 202 and through second substrate terminals 208 provided on the second lower pads 204. The first substrate terminals 206 and the second substrate terminals 208 may be connection terminals for connecting the interposer chip 200 to the package substrate 100. The first substrate terminals 206 may connect the first lower pads 202 to the first substrate pads 110. The second substrate terminals 208 may connect the second lower pads 204 to the second substrate pads 120. Based on positions of the first lower pads 202, the first substrate terminals 206 may be provided on the third region R3 of the bottom surface 200b of the interposer chip 200. Based on positions of the second lower pads 204, the second substrate terminals 208 may be provided on the fourth region R4 of the bottom surface 200b of the interposer chip 200. A second width W2 of the first substrate terminal 206 may be substantially the same as or similar to a fourth width W4 of the second substrate terminal 208. A second interval G2 between the first substrate terminals 206 may be substantially the same as a fourth interval G4 between the second substrate terminals 208. The first substrate terminals 206 and the second substrate terminals 208 may include solder balls or solder bumps.

A first underfill layer 107 may be provided between the package substrate 100 and the interposer chip 200. The first underfill layer 107 may surround the first substrate terminals 206 and the second substrate terminals 208, while filling a space between the package substrate 100 and the interposer chip 200.

The first semiconductor chip 300 may be disposed on the interposer chip 200. The first semiconductor chip 300 may be disposed on the top surface 200a of the interposer chip 200. A bottom surface of the first semiconductor chip 300 may be an active surface, and a top surface of the first semiconductor chip 300 may be an inactive surface. For example, the first semiconductor chip 300 may be disposed in a face-down state on the interposer chip 200.

The first semiconductor chip 300 may include a semiconductor material, such as silicon (Si). The first semiconductor chip 300 may include a first circuit layer 310 that faces the interposer chip 200. The first circuit layer 310 may include an integrated circuit formed on a semiconductor substrate. For example, the first circuit layer 310 may include a memory circuit. For example, the first semiconductor chip 300 may be a memory chip. Alternatively, or in addition, the first circuit layer 310 may include a logic circuit. For example, the first semiconductor chip 300 may be a logic chip. The first circuit layer 310 may include a wiring pattern, a dielectric pattern, and an electronic element such as a transistor. The wiring pattern of the first circuit layer 310 may be electrically connected to the integrated circuit. The wiring pattern may be formed of metal, such as copper (Cu). The dielectric pattern of the first circuit layer 310 may cover and protect the integrated circuit. The dielectric pattern may be formed of a single or multiple layer including, for example, at least one selected from silicon oxide (SiO), silicon nitride (SiN), silicon oxynitride (SiON), and porous dielectrics.

A plurality of first chip pads 320 may be disposed on the first circuit layer 310. For example, the first chip pads 320 may be exposed on a bottom surface of the first circuit layer 310. FIG. 1 depicts that the first chip pads 320 protrude onto the bottom surface of the first circuit layer 310, but the chip pad configuration is not limited thereto. The first chip pads 320 may have bottom surfaces substantially flat and coplanar with that of the first circuit layer 310. The first chip pads 320 may be coupled to the first circuit layer 310. The first chip pads 320 may be connected to the integrated circuit through the wiring pattern of the first circuit layer 310. The first chip pads 320 may include various metallic materials, such as copper (Cu), aluminum (Al), and/or nickel (Ni).

The first semiconductor chip 300 may be flip-chip mounted on the interposer chip 200. For example, the first semiconductor chip 300 may be mounted on the interposer chip 200 through first chip terminals 330 provided on the first chip pads 320. The first chip terminals 330 may be connection terminals for connecting the first semiconductor chip 300 to the interposer chip 200. The first chip terminals 330 may connect the first chip pads 320 of the first semiconductor chip 300 to the first upper pads 236 of the interposer chip 200. Based on a position of the first semiconductor chip 300, the first chip terminals 330 may be provided on the first region R1 of the top surface 200a of the interposer chip 200. The first chip terminals 330 may include solder balls or solder bumps. The first semiconductor chip 300 may be electrically connected to the package substrate 100 through the first chip terminals 330, the interposer chip 200, and the first substrate terminals 206.

Referring to FIGS. 1 to 3, a first width W1 of the first chip terminal 330 may be substantially the same as or similar to the second width W2 of the first substrate terminal 206. A first interval G1 between the first chip terminals 330 may be substantially the same as or similar to the second interval G2 between the first substrate terminals 206. The first chip terminals 330 may be vertically aligned with the first substrate terminals 206. For example, each of the first chip terminals 330 may be positioned on one of the first substrate terminals 206. In this sense, the first chip terminals 330 may one-to-one correspond to the first substrate terminals 206, and a pair of first chip terminals 330 may transceive the same electric signal with the first substrate terminal 206. A first chip terminal 330 may transceive the same electric signal with its corresponding first substrate terminal 206 The scope of the present disclosure, however, is not limited thereto, and the pair of first chip terminals 330 may transceive different electric signals with the first substrate terminal 206. A first chip terminal 330 may transceive different electric signals with its corresponding first substrate terminal 206. The pair of first chip terminals 330 may vertically overlap the first substrate terminal 206. A first chip terminal 330 may vertically overlap its corresponding first substrate terminal 206.

Referring to FIG. 1, a second underfill layer 340 may be provided between the first semiconductor chip 300 and the interposer chip 200. The second underfill layer 340 may surround the first chip terminals 330, while filling a space between the first semiconductor chip 300 and the interposer chip 200.

The second semiconductor chip 400 may be disposed on the interposer chip 200. The second semiconductor chip 400 may be horizontally spaced apart from the first semiconductor chip 300. The second semiconductor chip 400 may be disposed on the second region R2 of the top surface 200a of the interposer chip 200. A bottom surface of the second semiconductor chip 400 may be an active surface, and a top surface of the second semiconductor chip 400 may be an inactive surface. For example, the second semiconductor chip 400 may be disposed in a face-down state on the interposer chip 200.

The second semiconductor chip 400 may include a semiconductor material, such as silicon (Si). The second semiconductor chip 400 may include a second circuit layer 410 that faces the interposer chip 200. The second circuit layer 410 may include an integrated circuit formed on a semiconductor substrate. For example, the second circuit layer 410 may include a logic circuit. In this case, the second semiconductor chip 400 may be a logic chip. Alternatively, or in addition, the second circuit layer 410 may include a memory circuit. For example, the second semiconductor chip 400 may be a memory chip. The second circuit layer 410 may include a wiring pattern, a dielectric pattern, and an electronic element such as a transistor. The wiring pattern of the second circuit layer 410 may be electrically connected to the integrated circuit. The wiring pattern may be formed of metal, such as copper (Cu). The dielectric pattern of the second circuit layer 410 may cover and protect the integrated circuit. The dielectric pattern may be formed of a single or multiple layer including, for example, at least one selected from silicon oxide (SiO), silicon nitride (SiN), silicon oxynitride (SiON), and porous dielectrics.

A plurality of second chip pads 420 may be disposed on the second circuit layer 410. For example, the second chip pads 420 may be exposed on a bottom surface of the second circuit layer 410. FIG. 1 depicts that the second chip pads 420 protrude onto the bottom surface of the second circuit layer 410, but the chip pad configuration is not limited thereto. The second chip pads 420 may have bottom surfaces substantially flat and coplanar with that of the second circuit layer 410. The second chip pads 420 may be coupled to the second circuit layer 410. The second chip pads 420 may be connected to the integrated circuit through the wiring pattern of the second circuit layer 410. The second chip pads 420 may include various metallic materials, such as copper (Cu), aluminum (Al), and/or nickel (Ni).

The second semiconductor chip 400 may be flip-chip mounted on the interposer chip 200. For example, the second semiconductor chip 400 may be mounted on the interposer chip 200 through second chip terminals 430 provided on the second chip pads 420. The second chip terminals 430 may be connection terminals for connecting the second semiconductor chip 400 to the interposer chip 200. The second chip terminals 430 may connect the second chip pads 420 of the second semiconductor chip 400 to the second upper pads 238 of the interposer chip 200. Based on a position of the second semiconductor chip 400, the second chip terminals 430 may be provided on the second region R2 of the top surface 200a of the interposer chip 200. The second chip terminals 430 may include solder balls or solder bumps. The second semiconductor chip 400 may be electrically connected to the package substrate 100 through the second chip terminals 430, the interposer chip 200, and the second substrate terminals 208.

Referring to FIGS. 1 to 3, a third width W3 of the second chip terminal 430 may be substantially the same as or similar to the fourth width W4 of the second substrate terminal 208. A third interval G3 between the second chip terminals 430 may be substantially the same as or similar to the fourth interval G4 between the second substrate terminals 208. The second chip terminals 430 may be vertically aligned with the second substrate terminals 208. For example, each of the second chip terminals 430 may be positioned on one of the second substrate terminals 208. In this sense, the second chip terminals 430 may one-to-one correspond to the second substrate terminals 208, and a pair of second chip terminals 430 may transceive the same electric signal with the second substrate terminal 208. A second chip terminal 430 may transceive the same electric signal with its corresponding second substrate terminal 208. The scope of the present disclosure, however, is not limited thereto, and the pair of second chip terminals 430 may transceive different electric signals with the second substrate terminal 208. A second chip terminal 430 may transceive different electric signals with its corresponding second substrate terminal 208. The pair of second chip terminals 430 may vertically overlap the second substrate terminal 208. A second chip terminal 430 may vertically overlap its corresponding second substrate terminal 208.

The first width W1 of the first chip terminal 330 may be substantially the same as or similar to the third width W3 of the second chip terminal 430. The first interval G1 between the first chip terminals 330 may be substantially the same as the third interval G3 between the second chip terminals 430.

Referring to FIG. 1, a third underfill layer 440 may be provided between the second semiconductor chip 400 and the interposer chip 200. The third underfill layer 440 may surround the second chip terminals 430, while filling a space between the second semiconductor chip 400 and the interposer chip 200.

A molding layer 500 may be provided on the interposer chip 200. The molding layer 500 may cover the top surface 200a of the interposer chip 200. The molding layer 500 may surround the first semiconductor chip 300 and the second semiconductor chip 400. A top surface of the molding layer 500 may be located at the same level as that of the top surface of the first semiconductor chip 300 and/or that of the top surface of the second semiconductor chip 400. The molding layer 500 may include a dielectric material. For example, the molding layer 500 may include an epoxy molding compound (EMC).

According to some implementations of the present disclosure, in the interposer chip 200, the first upper pads 236 and the first lower pads 202 may transfer the same electric signal, and the second upper pads 238 and the second lower pads 204 may transfer the same electric signal. The first region R1 on which the first upper pads 236 are provided may overlap the third region R3 on which the first lower pads 202 are provided, and the second region R2 on which the second upper pads 238 are provided may overlap the fourth region R4 on which the second lower pads 204 are provided. Therefore, electrical pathways between the first and second upper pads 236 and 238 and the first and second lower pads 202 and 204 may require fewer horizontal wiring lines, and short electrical pathways may be provided between the first and second upper pads 236 and 238 and the first and second lower pads 202 and 204. As a result, it may be possible to provide a semiconductor package with improved electrical properties.

In addition, widths of the first and second substrate terminals 206 and 208 that connect the interposer chip 200 to the package substrate 100 may be the same as or similar to widths of the first and second chip terminals 330 and 430 that connect the first and second semiconductor chips 300 and 400 to the interposer chip 200. For example, the first and second substrate pads 110 and 120 of the package substrate 100 may be provided on the same or similar scale as the first and second lower pads 202 and 204 of the interposer chip 200 and as the first and second chip pads 320 and 420 of the first and second semiconductor chips 300 and 400. Accordingly, the interposer chip 200 may be mounted on the package substrate 100, and if necessary or beneficial, other semiconductor chip may be directly mounted on the package substrate 100. In such cases, it may be possible to provide a universally usable package substrate and a semiconductor package including the same.

For example, the first semiconductor chip 300 may be mounted on the interposer chip 200, and the second semiconductor chip 400 may be mounted on the package substrate 100, based on interoperability and compatibility of terminals, pads, and the like.

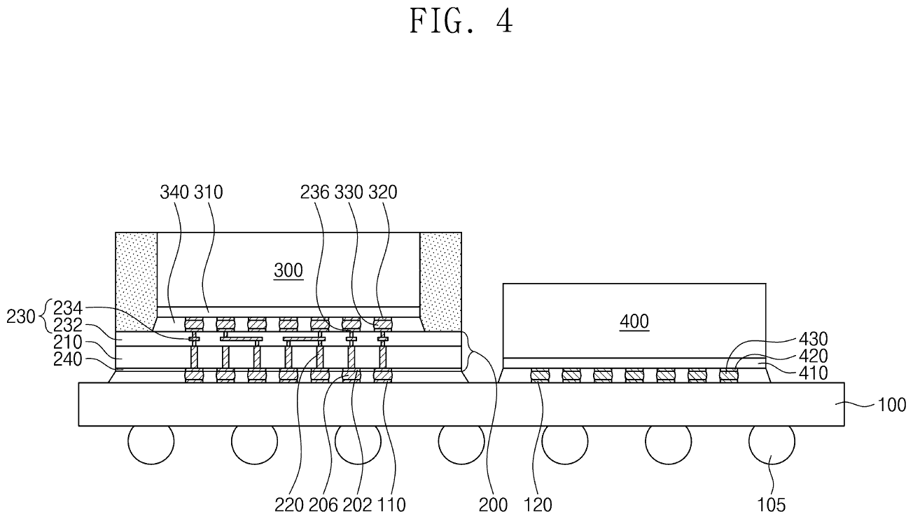

FIG. 4 is a cross-sectional view showing an example of a semiconductor package. As illustrated in FIG. 4, the interposer chip 200 may be mounted on the first substrate pads 110 of the package substrate 100. The first semiconductor chip 300 may be mounted on the interposer chip 200, and the interposer chip 200 may be provided thereon with the molding layer 500 that covers the first semiconductor chip 300. The second semiconductor chip 400 may be disposed on the second substrate pads 120 of the package substrate 100.

Alternatively, both of the first semiconductor chip 300 and the second semiconductor chip 400 may be directly mounted on the package substrate 100. The first semiconductor chip 300 may be disposed on the first substrate pads 110 of the package substrate 100. The second semiconductor chip 400 may be disposed on the second substrate pads 120 of the package substrate 100.

As discussed above, a single package substrate 100 may be used such that, if necessary, the interposer chip 200 may be mounted on the package substrate 100 or at least one selected from the first semiconductor chip 300 and the second semiconductor chip 400 may be directly mounted on the package substrate 100.

In the examples that follow, a detailed description of technical features repetitive to those discussed with reference to FIGS. 1 to 4 will be omitted for convenience of description, and differences thereof will be discussed in detail. The description provided with respect to elements and packages of FIGS. 1 to 4 applies equally to corresponding elements and packages described below, except where indicated otherwise or suggested otherwise by context. The same reference numerals may be allocated to the same components as those of the semiconductor packages discussed above.

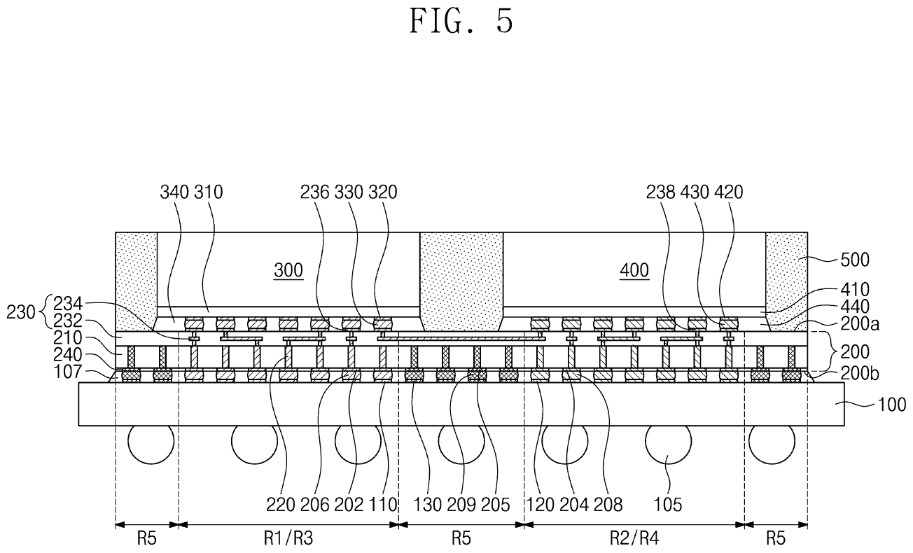

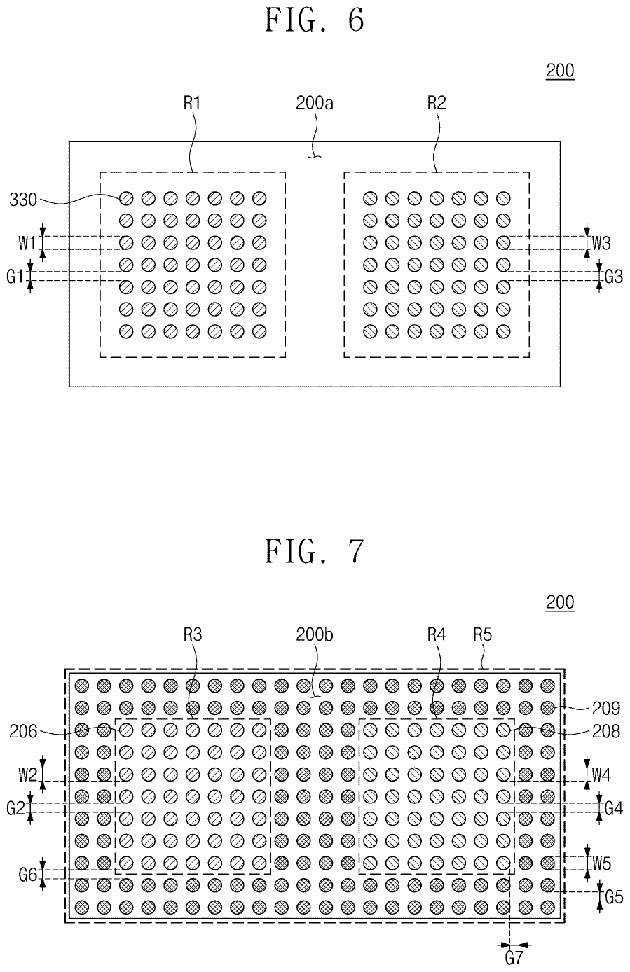

FIG. 5 is a cross-sectional view showing an example of a semiconductor package. FIG. 6 is a plan view showing a top surface of an interposer chip depicted in FIG. 5. FIG. 7 is a plan view showing a bottom surface of an interposer chip depicted in FIG. 5.

Referring to FIGS. 5 to 7, the package substrate 100 may include first substrate pads 110, second substrate pads 120, and third substrate pads 130 provided on the top surface of the package substrate 100. The third substrate pads 130 may be dummy pads.

An interposer chip 200 may be provided on the package substrate 100. The interposer chip 200 may include a base layer 210, through vias 220, and a redistribution layer 230.

The redistribution layer 230 may include first upper pads 236 and second upper pads 238 provided on a top surface of the redistribution layer 230. The first upper pads 236 may be provided on the first region R1. The second upper pads 238 may be provided on the second region R2.

First lower pads 202, second lower pads 204, and third lower pads 205 may be provided on the bottom surface 200b of the interposer chip 200. The through vias 220 may vertically penetrate the base layer 210 to be coupled to top surfaces of the first lower pads 202, top surfaces of the second lower pads 204, and top surfaces of the third lower pads 205. According to some implementations, the through vias 220 may not be connected to the third lower pads 205.

The bottom surface 200b of the interposer chip 200 may have a third region R3, a fourth region R4, and a fifth region R5. The first lower pads 202 may be provided on the third region R3. The second lower pads 204 may be provided on the fourth region R4. The third lower pads 205 may be provided on the fifth region R5. The first region R1 may vertically overlap the third region R3. The second region R2 may vertically overlap the fourth region R4. On the bottom surface 200b of the interposer chip 200, the fifth region R5 may be an area other than the third region R3 and the fourth region R4. The third lower pads 205 may be electrically insulated from the first semiconductor chip 300 and the second semiconductor chip 400.

The interposer chip 200 may be flip-chip mounted on the package substrate 100. For example, the interposer chip 200 may be mounted on the package substrate 100 through first substrate terminals 206 provided on the first lower pads 202, second substrate terminals 208 provided on the second lower pads 204, and third substrate terminals 209 provided on the third lower pads 205. The third substrate terminals 209 may connect the third lower pads 205 to the third substrate pads 130. The third substrate terminals 209 may be disposed between the first substrate terminals 206 and the second substrate terminals 208. Based on positions of the third lower pads 205, the third substrate terminals 209 may be provided on the fifth region R5 of the bottom surface 200b of the interposer chip 200. The third substrate terminals 209 may be electrically insulated from the first semiconductor chip 300 and the second semiconductor chip 400. For example, the third substrate terminals 209 may be dummy terminals.

A fifth width W5 of the third substrate terminal 209 may be substantially the same as or similar to the second width W2 of the first substrate terminal 206 and the fourth width W4 of the second substrate terminal 208. A fifth interval G5 between the third substrate terminals 209 may be substantially the same as the second interval G2 between the first substrate terminals 206 and the fourth interval G4 between the second substrate terminals 208.

A sixth interval G6 between the third substrate terminal 209 and the first substrate terminal 206 that are adjacent to each other among the third substrate terminals 209 and the first substrate terminals 206 may be about 0.5 times to about 2 times the second interval G2 between the first substrate terminals 206. A seventh interval G7 between the third substrate terminal 209 and the second substrate terminal 208 that are adjacent to each other among the third substrate terminals 209 and the second substrate terminals 208 may be about 0.5 times to about 2 times the fourth interval G4 between the second substrate terminals 208.

A first underfill layer 107 may be provided between the package substrate 100 and the interposer chip 200. The first underfill layer 107 may surround the second substrate terminals 208 and the third substrate terminals 209, while filling a space between the package substrate 100 and the interposer chip 200.

According to some implementations, when viewed in a plan view, the first and second substrate terminals 206 and 208 for electric signals may not be provided between the first semiconductor chip 300 and the second semiconductor chip 400, on one side of the first semiconductor chip 300, and on one side of the second semiconductor chip 400. The third substrate terminals 209 may be provided between the first semiconductor chip 300 and the second semiconductor chip 400, on one side of the first semiconductor chip 300, and on one side of the second semiconductor chip 400, and thus the interposer chip 200 may be strongly supported by the first, second, and third substrate terminals 206, 208, and 209. As a result, it may be possible to provide a semiconductor package with improved structural stability.

Substrate terminals, or the first, second, and third substrate terminals 206, 208, and 209, provided below the interposer chip 200 may be disposed with a relatively regular interval. Thus, a load of the interposer chip 200 may be evenly dispersed on the first, second, and third substrate terminals 206, 208, and 209, and the interposer chip 200 may be firmly supported by the first, second, and third substrate terminals 206, 208, and 209. In addition, during the fabrication of a semiconductor package, the first underfill layer 107 may be easily introduced into between the first, second, and third substrate terminals 206, 208, and 209.

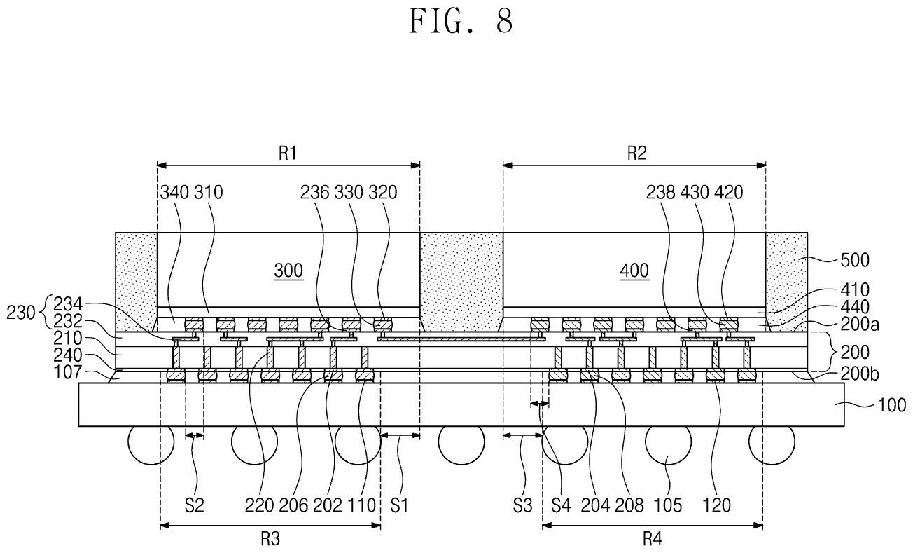

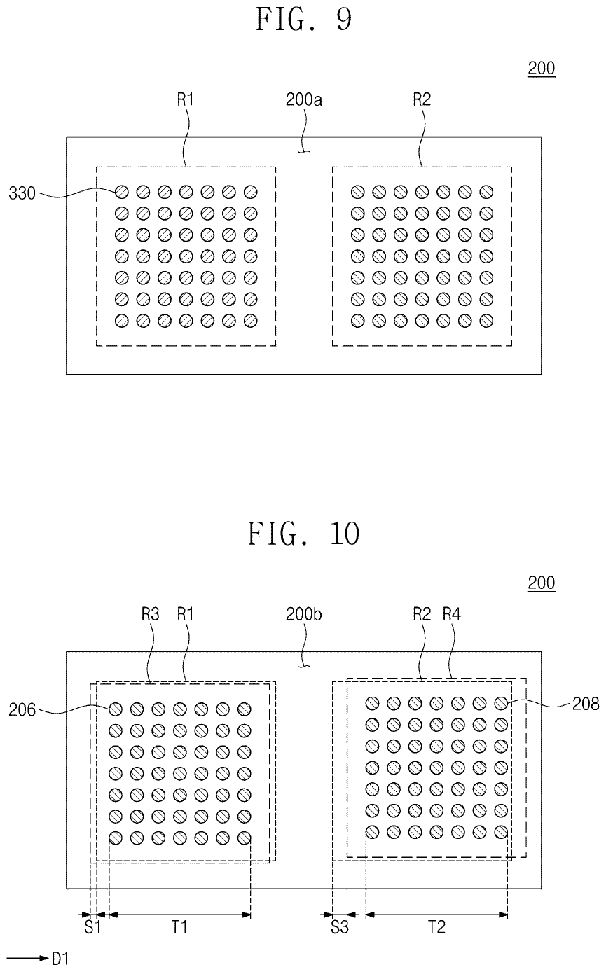

FIG. 8 is a cross-sectional view showing an example of a semiconductor package. FIG. 9 is a plan view showing a top surface of an interposer chip depicted in FIG. 8. FIG. 10 is a plan view showing a bottom surface of an interposer chip depicted in FIG. 8. In FIG. 10, a first region and a third region are shown together for convenience of description.

FIGS. 1 to 7 depict that the first region R1 vertically overlaps the third region R3, and that the second region R2 vertically overlaps the fourth region R4. For example, FIGS. 1 to 7 depict that the first chip terminals 330 are vertically aligned with the first substrate terminals 206, and that the second chip terminals 430 are vertically aligned with the second substrate terminals 208. The relative arrangements, however, are not limited thereto.

Referring to FIGS. 8 to 10, the first region R1 may vertically overlap at least a portion of the third region R3. The first region R1 and the third region R3 may be shifted from each other in a horizontal direction, e.g., be partially non-overlapping. When viewed in a plan view, a shift distance S1 in an arbitrary first direction D1 between the first region R1 and the third region R3 may be about 0 to 0.5 times a width in the first direction D1 of the first region R1 or a width in the first direction D1 of the third region R3. For example, when viewed in a plan view, an arrangement of the first substrate terminals 206 may be the same as that of the first chip terminals 330, with a shift therebetween. A shift distance S2 in the first direction D1 between the first substrate terminals 206 and the first chip terminals 330 may be about 0 to 0.5 times a distance T1 between two first substrate terminals 206 that are positioned farthest in the first direction D1 or a distance between two first chip terminals 330 that are positioned farthest in the first direction D1. The first direction D1 may be an arbitrary direction parallel to the top surface 200a of the interposer chip 200 or the bottom surface 200b of the interposer chip 200.

The second region R2 may vertically overlap at least a portion of the fourth region R4. The second region R2 and the fourth region R4 may be shifted from each other in a horizontal direction. When viewed in a plan view, a shift distance S3 in the first direction D1 between the second region R2 and the fourth region R4 may be about 0 to 0.5 times a width in the first direction D1 of the second region R2 or a width in the first direction D1 of the fourth region R4. For example, when viewed in a plan view, an arrangement of the second substrate terminals 208 may be the same as that of the second chip terminals 430, with a shift therebetween. A shift distance S4 in the first direction D1 between the second substrate terminals 208 and the second chip terminals 430 may be about 0 to 0.5 times a distance T2 between two second substrate terminals 208 that are positioned farthest in the first direction D1 or a distance between two second chip terminals 430 that are positioned farthest in the first direction D1.

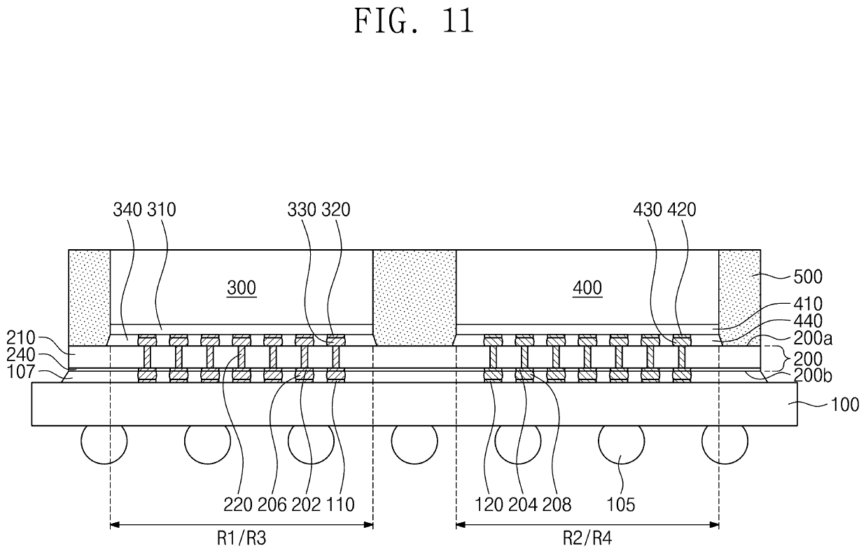

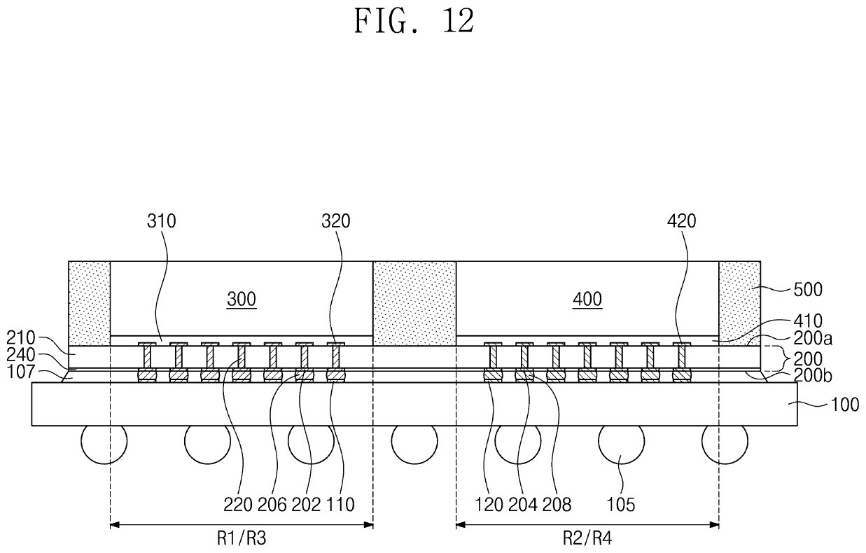

FIG. 11 is a cross-sectional view showing an example of a semiconductor package.

Referring to FIG. 11, the interposer chip 200 may not include the redistribution layer (see 230 of FIG. 1). The top surface 200a of the interposer chip 200 may be a top surface of the base layer 210. Thus, the through vias 220 may be exposed on the top surface 200a of the interposer chip 200.

The first semiconductor chip 300 may be flip-chip mounted on the interposer chip 200. For example, the first semiconductor chip 300 may be mounted on the interposer chip 200 through first chip terminals 330 provided on the first chip pads 320. The first chip terminals 330 may connect the first chip pads 320 of the first semiconductor chip 300 to the through vias 220 of the interposer chip 200.

The second semiconductor chip 400 may be flip-chip mounted on the interposer chip 200. For example, the second semiconductor chip 400 may be mounted on the interposer chip 200 through second chip terminals 430 provided on the second chip pads 420. The second chip terminals 430 may connect the second chip pads 420 of the second semiconductor chip 400 to the through vias 220 of the interposer chip 200.

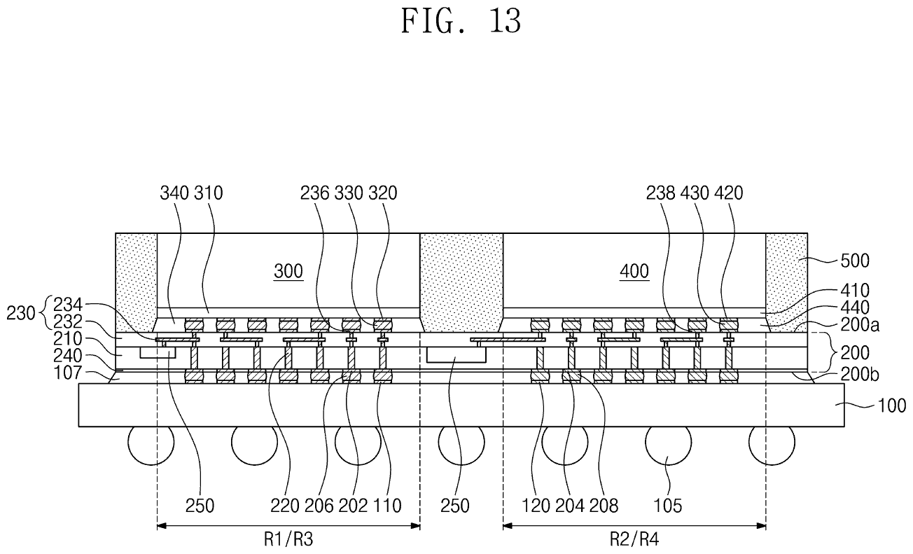

FIG. 12 is a cross-sectional view showing an example of a semiconductor package.

Referring to FIG. 12, the interposer chip 200 may not include the redistribution layer (see 230 of FIG. 1). The top surface 200a of the interposer chip 200 may be a top surface of the base layer 210. Thus, the through vias 220 may be exposed on the top surface 200a of the interposer chip 200.

The first semiconductor chip 300 may be mounted on the interposer chip 200. For example, the first semiconductor chip 300 may be disposed on the interposer chip 200. The first semiconductor chip 300 may be disposed in a face-down state on the interposer chip 200. The first chip pads 320 of the first semiconductor chip 300 may be vertically aligned with the through vias 220 of the interposer chip 200. The first semiconductor chip 300 and the interposer chip 200 may be in contact with each other to allow the first chip pads 320 and the through vias 220 to have connection with each other on the first region R1.

The first semiconductor chip 300 may be connected to the interposer chip 200. For example, the first semiconductor chip 300 and the interposer chip 200 may be in contact with each other. On an interface between the first semiconductor chip 300 and the interposer chip 200, the through vias 220 of the interposer chip 200 may be bonded to the first chip pads 320 of the first semiconductor chip 300. In this case, the through vias 220 and the first chip pads 320 may constitute an intermetallic hybrid bonding. In this description, the term “hybrid bonding” may denote a bonding in which two components of the same kind are merged at an interface therebetween. For example, the through via 220 and the first chip pad 320 that are bonded to each other may have a continuous configuration, and an invisible interface may be present between the through via 220 and the first chip pad 320. For example, the through via 220 and the first chip pad 320 may be formed of the same material, and thus no interface may be present between the through via 220 and the first chip pad 320. In this sense, the through via 220 and the first chip pad 320 may be provided as a single component. For example, the through via 220 and the first chip pad 320 may be bonded to constitute a single unitary piece.

The second semiconductor chip 400 may be mounted on the interposer chip 200. For example, the second semiconductor chip 400 may be disposed on the interposer chip 200. The second semiconductor chip 400 may be disposed in a face-down state on the interposer chip 200. The second chip pads 420 of the second semiconductor chip 400 may be vertically aligned with the through vias 220 of the interposer chip 200. The second semiconductor chip 400 and the interposer chip 200 may be in contact with each other to allow the second chip pads 420 and the through vias 220 to have connection with each other on the second region R2.

The second semiconductor chip 400 may be connected to the interposer chip 200. For example, the second semiconductor chip 400 and the interposer chip 200 may be in contact with each other. On an interface between the second semiconductor chip 400 and the interposer chip 200, the through vias 220 of the interposer chip 200 may be bonded to the second chip pads 420 of the second semiconductor chip 400. In this case, the through vias 220 and the second chip pads 420 may constitute an intermetallic hybrid bonding. For example, the through via 220 and the second chip pad 420 that are bonded to each other may have a continuous configuration, and an invisible interface may be present between the through via 220 and the second chip pad 420. For example, the through via 220 and the second chip pad 420 may be formed of the same material, and thus no interface may be present between the through via 220 and the second chip pad 420. In this sense, the through via 220 and the second chip pad 420 may be provided as a single component. For example, the through via 220 and the second chip pad 420 may be combined to constitute a single unitary piece.

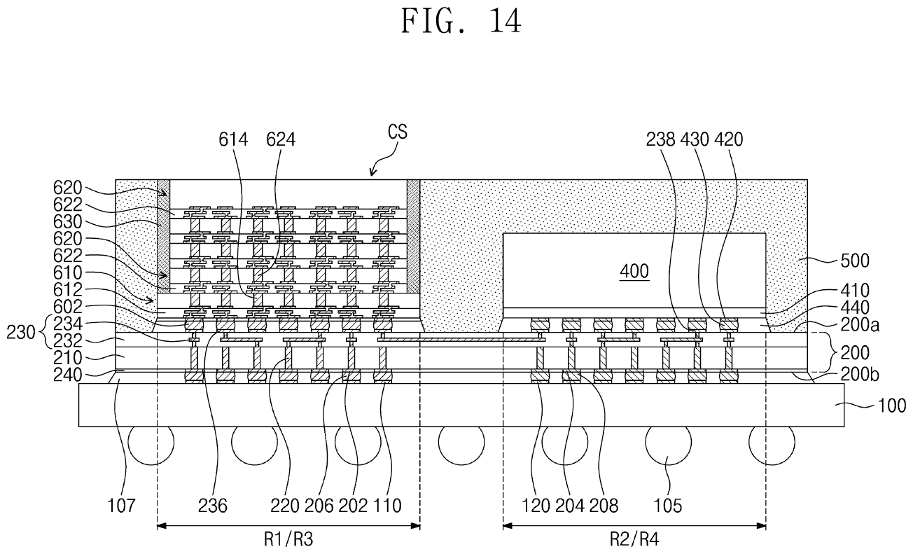

FIG. 13 is a cross-sectional view showing an example of a semiconductor package.

Referring to FIG. 13, the interposer chip 200 may include at least one electronic element 250. For example, the interposer chip 200 may be provided on the package substrate 100. The interposer chip 200 may include a base layer 210, through vias 220, and a redistribution layer 230.

The base layer 210 may include a semiconductor substrate. The electronic element 250 may be provided on an upper portion of the base layer 210. For example, the electronic element 250 may include a transistor, a circuit line, or a passive element formed on a top surface of the semiconductor substrate. The passive element may include a capacitor, a resistor, or an inductor.

The redistribution layer 230 may be disposed on the top surface of the base layer 210. The redistribution layer 230 may have chip wiring patterns 234 connected to the through vias 220 and the electronic element 250. The electronic element 250 may be connected through the chip wiring patterns 234 to either the first upper pads 236 or the second upper pads 238. The electronic element 250 may be connected through the redistribution layer 230 to either the first semiconductor chip 300 of the second semiconductor chip 400.

According to some implementations of the present disclosure, a passive element for the first semiconductor chip 300 or the second semiconductor chip 400 may be provided as the electronic element 250 in the interposer chip 200, and/or a portion of integrated circuits of the first and second semiconductor chips 300 and 400 may be provided as the electronic element 250 in the interposer chip 200. Therefore, the first semiconductor chip 300 and the second semiconductor chip 400 may have reduced size, and a semiconductor package as a whole may have a compact size.

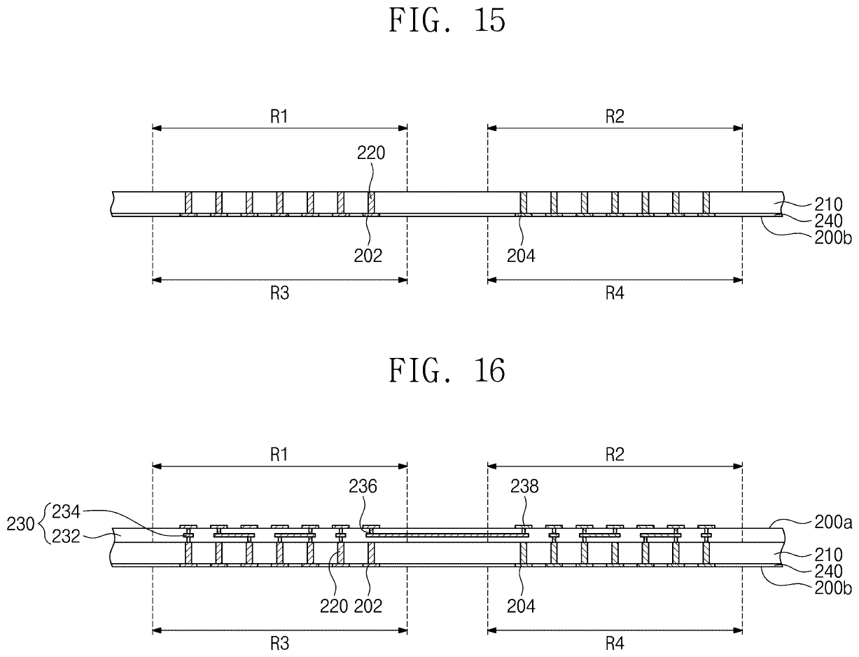

FIG. 14 is a cross-sectional view showing an example of a semiconductor package.

Referring to FIG. 14, a semiconductor package may include a chip stack CS in place of a semiconductor chip (compare to 300 of FIG. 1).

A second semiconductor chip 400 may be disposed on the interposer chip 200. The second semiconductor chip 400 may be disposed on the second region R2 of the top surface 200a of the interposer chip 200. The second semiconductor chip 400 may include a logic circuit. For example, the second semiconductor chip 400 may be a logic chip. For example, the second semiconductor chip 400 may include a graphic processing unit.

The chip stack CS may be disposed on the interposer chip 200. The chip stack CS may be disposed on the first region R1 of the top surface 200a of the interposer chip 200.

The chip stack CS may include a base substrate, third semiconductor chips 620 stacked on the base substrate, and an inner molding layer 630 that surrounds the third semiconductor chips 620. The following will describe in detail a configuration of the chip stack CS.

The base substrate may be a base semiconductor chip 610. For example, the base substrate may be a wafer-level semiconductor substrate formed of a semiconductor material such as silicon (Si). In this description below, the base semiconductor chip 610 and the base substrate may indicate the same component and may be allocated with the same reference numeral.

The base semiconductor chip 610 may include a base circuit layer 612 and base through electrodes 614. The base circuit layer 612 may be provided on a bottom surface of the base semiconductor chip 610. The base circuit layer 612 may include an integrated circuit. For example, the base circuit layer 612 may be a memory circuit. The base semiconductor chip 610 may be a memory chip, such as a dynamic random-access memory (DRAM), a static random-access memory (SRAM), a magnetic random-access memory (MRAM), or a Flash memory. The base semiconductor chip 610 may be a logic chip. The base through electrodes 614 may vertically penetrate the base semiconductor chip 610. The base through electrodes 614 may be electrically connected to the base circuit layer 612. The bottom surface of the base semiconductor chip 610 may be an active surface. According to some implementations, the base substrate may be a wiring substrate that does not include the base semiconductor chip 610.

The third semiconductor chip 620 may be mounted on the base semiconductor chip 610. The third semiconductor chip 620 and the base semiconductor chip 610 may constitute a chip-on-wafer (COW) structure. The third semiconductor chip 620 may have a width less than that of the base semiconductor chip 610.

The third semiconductor chip 620 may include a third circuit layer 622 and chip through electrodes 624. The third circuit layer 622 may include a memory circuit. For example, the third semiconductor chip 620 may be a memory chip, such as a dynamic random-access memory (DRAM), a static random-access memory (SRAM), a magnetic random-access memory (MRAM), or a Flash memory. The third circuit layer 622 may include the same circuit as that of the base circuit layer 612, but the circuitry is not limited thereto. The chip through electrodes 624 may vertically penetrate the third semiconductor chip 620. The chip through electrodes 624 may be electrically connected to the third circuit layer 622. The third semiconductor chip 620 may have a bottom surface as an active surface.

The third semiconductor chip 620 may be coupled to the base semiconductor chip 610. For example, pads of the third circuit layer 622 of the third semiconductor chip 620 may be in contact with top surfaces of the base through electrodes 614 exposed on a top surface of the base semiconductor chip 610. Alternatively, or in addition, the third semiconductor chip 620 may be mounted on the top surfaces of the base through electrodes 614 through terminals provided on the pads of the third circuit layer 622.

The third semiconductor chip 620 may be provided in plural. For example, a plurality of third semiconductor chips 620 may be stacked on the base semiconductor chip 610. The number of stacked third semiconductor chips 620 may be about 4 to 32, or another number. An uppermost third semiconductor chip 620 may not include the chip through electrodes 624. The uppermost third semiconductor chip 620 may have a thickness greater than those of other third semiconductor chips 620 that underlie the uppermost third semiconductor chip 620.

Neighboring third semiconductor chips 620 may be bonded to each other. For example, the pads of the third circuit layer 622 of each of the third semiconductor chips 620 may be in contact with top surfaces of the chip through electrodes 624 exposed on a top surface of an underlying third semiconductor chip 620. Alternatively, or in addition, the third semiconductor chips 620 may be mounted on the top surfaces of the chip through electrodes 624 through terminals provided on the pads of the third circuit layer 622.

The inner molding layer 630 may be provided on the top surface of the base semiconductor chip 610. The inner molding layer 630 may cover the base semiconductor chip 610 and surround the third semiconductor chips 620. The inner molding layer 630 may have a top surface coplanar with that of the uppermost third semiconductor chip 620, and the uppermost third semiconductor chip 620 may be exposed from the inner molding layer 630. The inner molding layer 630 may include a dielectric polymer material, such as an epoxy molding compound (EMC).

A plurality of connection terminals 602 may be provided on a bottom surface of the chip stack CS or a bottom surface of the base circuit layer 612. The chip stack CS may be coupled through the connection terminals 602 to the first upper pads 236 of the interposer chip 200.

FIGS. 15 to 20 are cross-sectional views showing an example of a method of fabricating a semiconductor package.

Referring to FIG. 15, a base layer 210 may be provided. The base layer 210 may be formed on a single wafer. For example, the single wafer may be used to form a plurality of interposer chips. For convenience of description, the following will describe an example where one interposer chip is formed. For example, a semiconductor wafer may be provided. A top surface of the semiconductor wafer may have a first region R1 and a second region R2 that are spaced apart from each other. A bottom surface of the semiconductor wafer may have a third region R3 and a fourth region R4 that are spaced apart from each other. The first region R1 and the third region R3 may be vertically aligned with each other, and the second region R2 and the fourth region R4 may be vertically aligned with each other. A plurality of through holes may be formed in the semiconductor wafer, and then the through holes may be filled with a conductive material to form through vias 220. The through vias 220 may be formed on the first region R1 and the second region R2.

First lower pads 202, second lower pads 204, and a passivation layer 240 may be formed on a bottom surface of the base layer 210. For example, a dielectric material may be deposited or coated on the bottom surface of the base layer 210 to form the passivation layer 240, the passivation layer 240 may be patterned to form openings that expose the through vias 220, and then the opening may be filled with a conductive material to form the first lower pads 202 and the second lower pads 204. As another example, a conductive layer may be formed on the bottom surface of the base layer 210, the conductive layer may be patterned to form the first lower pads 202 and the second lower pads 204, and the passivation layer 240 may be formed to surround the first lower pads 202 and the second lower pads 204 on the bottom surface of the base layer 210. The first lower pads 202 may be formed on the third region R3, and the second lower pads 204 may be formed on the fourth region R4.

Referring to FIG. 16, a redistribution layer 230 may be formed on the base layer 210. For example, a dielectric material may be deposited on a top surface of the base layer 210, and then a patterning process may be performed to form a chip dielectric pattern 232. A conductive material may be deposited on the chip dielectric pattern 232, and then a patterning process may be performed to form chip wiring patterns 234. The processes may be repeated to form the redistribution layer 230.

First upper pads 236 and second upper pads 238 may be formed on a top surface of the redistribution layer 230. For example, a conductive material may be deposited on the top surface of the redistribution layer 230, and then a patterning process may be performed to form the first upper pads 236 and the second upper pads 238. Alternatively, the first upper pads 236 and the second upper pads 238 may be portions of the chip wiring patterns 234 exposed on a top surface of the chip dielectric pattern 232. The first upper pads 236 may be formed on the first region R1, and the second upper pads 238 may be formed on the second region R2.

As discussed above, an interposer chip 200 may be formed on a partial region of the semiconductor wafer.

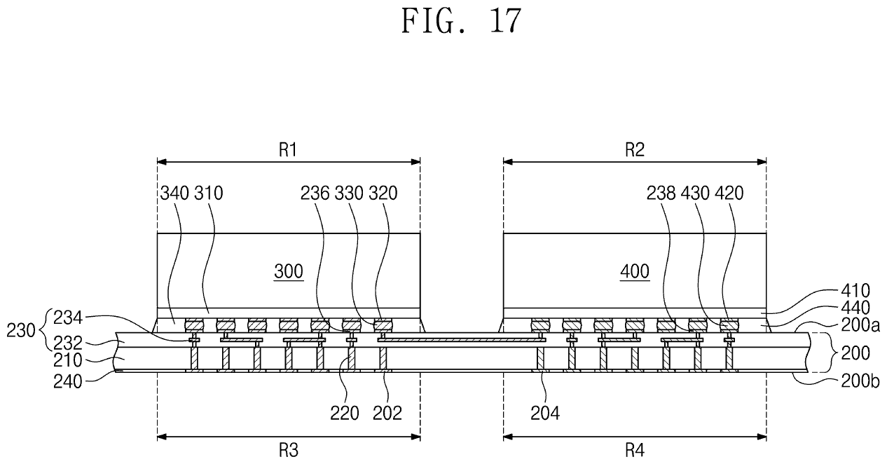

Referring to FIG. 17, a first semiconductor chip 300 may be provided. The first semiconductor chip 300 may be substantially the same as or similar to the first semiconductor chip 300 discussed with reference to FIG. 1. The first semiconductor chip 300 may be mounted on the interposer chip 200. The first semiconductor chip 300 may be flip-chip mounted. For example, first chip terminals 330 may be provided on first chip pads 320 of the first semiconductor chip 300. The first semiconductor chip 300 may be positioned on the first region R1 of the interposer chip 200 to allow the first chip terminals 330 to contact the first upper pads 236. Afterwards, a reflow process may be performed on the first chip terminals 330. A second underfill layer 340 may be formed between the first semiconductor chip 300 and the interposer chip 200.

A second semiconductor chip 400 may be provided. The second semiconductor chip 400 may be substantially the same as or similar to the second semiconductor chip 400 discussed with reference to FIG. 1. The second semiconductor chip 400 may be mounted on the interposer chip 200. The second semiconductor chip 400 may be flip-chip mounted. For example, second chip terminals 430 may be provided on second chip pads 420 of the second semiconductor chip 400. The second semiconductor chip 400 may be positioned on the second region R2 of the interposer chip 200 to allow the second chip terminals 430 to contact the second upper pads 238. Afterwards, a reflow process may be performed on the second chip terminals 430. A third underfill layer 440 may be formed between the second semiconductor chip 400 and the interposer chip 200.

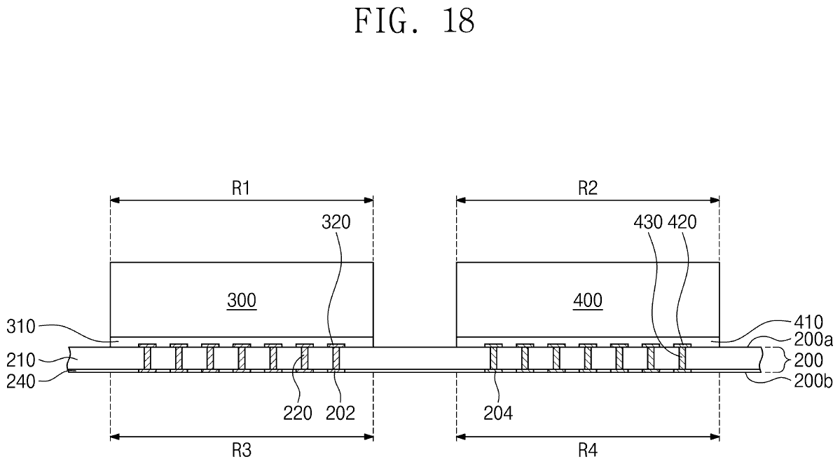

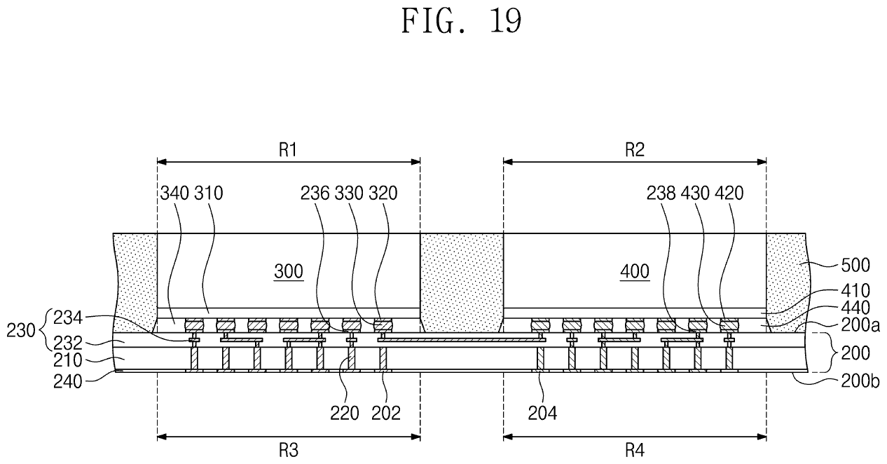

According to some implementations, the first semiconductor chip 300 and the second semiconductor chip 400 may be directly mounted on the interposer chip 200. Referring to FIG. 18, on a resultant structure of FIG. 15, the first semiconductor chip 300 and the second semiconductor chip 400 may be provided.

The first semiconductor chip 300 may be bonded to the interposer chip 200. The first semiconductor chip 300 and the interposer chip 200 may be bonded in a chip-to-wafer fashion. An active surface of the first semiconductor chip 300 may face an inactive surface of the interposer chip 200. The first semiconductor chip 300 may be placed on the interposer chip 200 to allow the first chip pads 320 of the first semiconductor chip 300 to vertically align with the through vias 220 of the interposer chip 200.

A thermal treatment process may be performed on the first semiconductor chip 300 and the interposer chip 200. The thermal treatment process may bond the first chip pads 320 to the through vias 220. For example, the first chip pad 320 and the through via 220 may be bonded to constitute a single unitary piece. The first chip pad 320 and the through via 220 may be automatically bonded. For example, the first chip pad 320 and the through via 220 may be formed of the same material (e.g., copper (Cu)), and may be bonded to each other by an intermetallic hybrid bonding process resulting from surface activation at an interface between the first chip pad 320 and the through via 220 that are in contact with each other. In a bonding process for the first semiconductor chip 300 and the interposer chip 200, the first semiconductor chip 300 may be close to face the interposer chip 200 for easy bonding.

The second semiconductor chip 400 may be bonded to the interposer chip 200. The second semiconductor chip 400 and the interposer chip 200 may be bonded in a chip-to-wafer fashion. An active surface of the second semiconductor chip 400 may face the inactive surface of the interposer chip 200. The second semiconductor chip 400 may be placed on the interposer chip 200 to allow the second chip pads 420 of the second semiconductor chip 400 to vertically align with the through vias 220 of the interposer chip 200.

A thermal treatment process may be performed on the second semiconductor chip 400 and the interposer chip 200. The thermal treatment process may bond the second chip pads 420 to the through vias 220. For example, the second chip pad 420 and the through via 220 may be bonded to constitute a single unitary piece. The second chip pad 420 and the through via 220 may be automatically bonded. For example, the second chip pad 420 and the through via 220 may be formed of the same material (e.g., copper (Cu)), and may be bonded to each other by an intermetallic hybrid bonding process resulting from surface activation at an interface between the second chip pad 420 and the through via 220 that are in contact with each other. In a bonding process for the second semiconductor chip 400 and the interposer chip 200, the second semiconductor chip 400 may be close to face the interposer chip 200 for easy bonding.

The following description will focus on, or continue from, the example of FIG. 17.

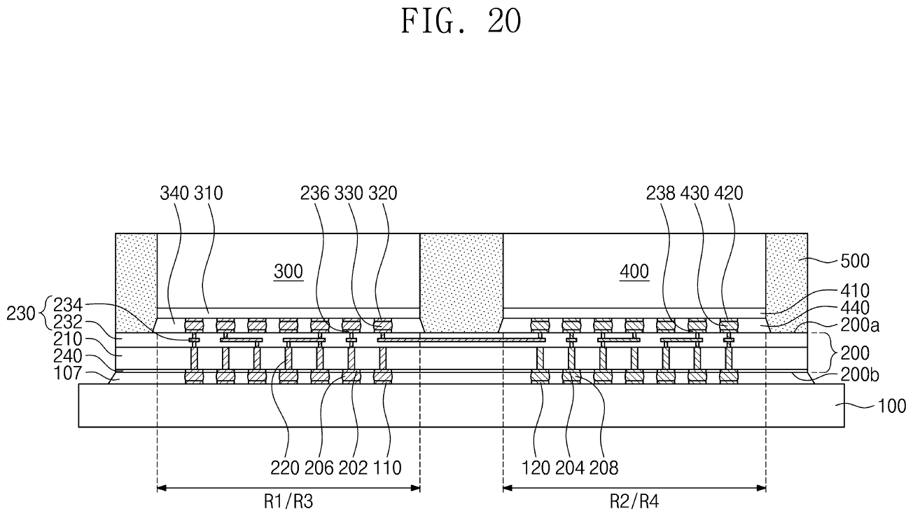

Referring to FIG. 19, a molding layer 500 may be formed on the interposer chip 200. For example, a molding member may be coated on the interposer chip 200 to cover the first semiconductor chip 300 and the second semiconductor chip 400, and then the molding member may be cured to form the molding layer 500. Thereafter, a thinning process may be performed on a top surface of the molding layer 500. The thinning process may continue until a top surface of the first semiconductor chip 300 is exposed or a top surface of the second semiconductor chip 400 is exposed. The thinning process may include a chemical mechanical polishing (CMP) process.

Referring to FIG. 20, a singulation process may be performed on a resultant structure of FIG. 19. The singulation process may cut the semiconductor wafer and the molding layer 500. The singulation process may separate the interposer chip 200 from the semiconductor wafer.

After that, the interposer chip 200 may be mounted on a package substrate 100. The interposer chip 200 may be flip-chip mounted. For example, first substrate terminals 206 may be provided on the first lower pads 202 of the interposer chip 200. Second substrate terminals 208 may be provided on the second lower pads 204 of the interposer chip 200. The interposer chip 200 may be placed on the package substrate 100 to allow the first substrate terminals 206 to contact the first substrate pads 110 and the second substrate terminals 208 to contact the second substrate pads 120. Afterwards, a reflow process may be performed on the first substrate terminals 206 and the second substrate terminals 208. A first underfill layer 107 may be provided between the package substrate 100 and the interposer chip 200.

Referring back to FIG. 1, external terminals 105 may be attached below the package substrate 100.

Based on some implementations of the semiconductor package configurations described above, electrical pathways between upper pads and lower pads of an interposer chip may require fewer horizontal wiring lines, and short electrical pathways may be provided between the upper pads and the lower pads. The semiconductor packages may thus improve in electrical properties. In addition, substrate pads of a package substrate may be provided on the same or similar scale as the lower pads of the interposer chip and as chip pads of semiconductor chips. Accordingly, the interposer chip may be mounted on the package substrate, and if necessary or beneficial, other semiconductor chip may be directly mounted on the package substrate. In such cases, it may be possible to provide a universally usable package substrate and the semiconductor package including the same.

In a semiconductor package according to some implementations of the present disclosure, when viewed in a plan view, dummy terminals may be provided between semiconductor chips and on one side of semiconductor chips, and thus the interposer chip may be strongly supported by substrate terminals and the dummy terminals. As a result, the semiconductor package may have improved structural stability.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the present disclosure has been described with reference to various examples, it will be apparent to those of ordinary skill in the art that various changes and modifications may be made thereto without departing from the spirit and scope of the present disclosure as set forth in the following claims.

What is claimed is

1. A semiconductor package, comprising:
a package substrate;
an interposer chip on the package substrate;
a first semiconductor chip mounted on the interposer chip; and
a second semiconductor chip mounted on the interposer chip and horizontally spaced apart from the first semiconductor chip,
wherein the interposer chip is mounted on the package substrate through a plurality of first connection terminals and a plurality of second connection terminals, the first and second connection terminals being on a bottom surface of the interposer chip,
wherein the first semiconductor chip is mounted on the interposer chip through a plurality of third connection terminals on a bottom surface of the first semiconductor chip,
wherein the second semiconductor chip is mounted on the interposer chip through a plurality of fourth connection terminals on a bottom surface of the second semiconductor chip,
wherein a first width of the plurality of first connection terminals is a same as a third width of the plurality of third connection terminals,
wherein a first interval between the plurality of first connection terminals is a same as a third interval between the plurality of third connection terminals,
wherein a second width of the plurality of second connection terminals is a same as a fourth width of the plurality of fourth connection terminals, and
wherein a second interval between the plurality of second connection terminals is a same as a fourth interval between the plurality of fourth connection terminals.

2. The semiconductor package of claim 1,
wherein the bottom surface of the interposer chip comprises:
a first region on which the plurality of first connection terminals are provided; and
a second region on which the plurality of second connection terminals are provided,
wherein a top surface of the interposer chip comprises:
a third region on which the plurality of third connection terminals are provided; and
a fourth region on which the plurality of fourth connection terminals are provided,
wherein the first region vertically overlaps at least a portion of the third region, and
wherein the second region vertically overlaps at least a portion of the fourth region.

3. The semiconductor package of claim 2, wherein
an arrangement of the plurality of first connection terminals is a same as an arrangement of the plurality of third connection terminals, and
the arrangement of the plurality of first connection terminals and the arrangement of the plurality of third connection terminals are shifted, with respect to one another, in a first direction parallel to the top surface of the interposer chip.

4. The semiconductor package of claim 2, wherein:
each of the plurality of third connection terminals is positioned above and overlaps a corresponding one of the plurality of first connection terminals, and
each of the plurality of fourth connection terminals is positioned above and overlaps a corresponding one of the plurality of second connection terminals.

5. The semiconductor package of claim 1, wherein the bottom surface of the interposer chip comprises:
a first region on which the plurality of first connection terminals are provided;
a second region on which the plurality of second connection terminals are provided; and
a third region that is an area other than the first region and the second region,
wherein the interposer chip further comprises a plurality of dummy terminals on the bottom surface of the interposer chip and on the third region,
wherein a fifth width of the plurality of dummy terminals is a same as the third width of the plurality of third connection terminals or the fourth width of the plurality of fourth connection terminals, and
wherein a fifth interval between the dummy terminals is a same as the third interval between the third connection terminals or the fourth interval between the fourth connection terminals.

6. The semiconductor package of claim 5, wherein:
a sixth interval between a first dummy terminal of the plurality of dummy terminals and a third connection terminal of the plurality of third connection terminals, the first dummy terminal and the third connection terminal adjacent to one another, is 0.5 times to two times the third interval between the plurality of third connection terminals, and
a seventh interval between a second dummy terminal of the plurality of dummy terminals and a fourth connection terminal of the plurality of fourth connection terminals, the second dummy terminal and the fourth connection terminal adjacent to one another, is 0.5 times to two times the fourth interval between the plurality of fourth connection terminals.

7. The semiconductor package of claim 1, wherein the interposer chip comprises:
a base layer;
a plurality of through vias that extend in the base layer; and
a plurality of lower pads on a bottom surface of the base layer, wherein the plurality of through vias are electrically coupled to the plurality of lower pads, and
wherein the plurality of first connection terminals and the plurality of second connection terminals are coupled to the plurality of lower pads.

8. The semiconductor package of claim 7, wherein the interposer chip comprises a redistribution layer on a top surface of the base layer, wherein the plurality of through vias are coupled to the redistribution layer,
wherein the redistribution layer comprises a plurality of upper pads on a top surface of the redistribution layer, wherein the plurality of third connection terminals and the plurality of fourth connection terminals are electrically coupled to the plurality of upper pads, and
wherein the plurality of upper pads are vertically aligned with the plurality of lower pads.

9. The semiconductor package of claim 7, wherein the interposer chip further comprises a passive element on a top surface of the base layer.

10. The semiconductor package of claim 7, wherein the base layer comprises a semiconductor substrate.

11. The semiconductor package of claim 1, wherein:
the plurality of first connection terminals and the plurality of third connection terminals are electrically connected to the first semiconductor chip, and
the plurality of second connection terminals and the plurality of fourth connection terminals are electrically connected to the second semiconductor chip.

12. A semiconductor package, comprising:
a package substrate;
an interposer chip on the package substrate;
a first semiconductor chip mounted on the interposer chip;
a second semiconductor chip mounted on the interposer chip and horizontally spaced apart from the first semiconductor chip;
a plurality of first connection terminals on a first region of a bottom surface of the interposer chip, wherein the plurality of first connection terminals electrically connect the interposer chip and the package substrate to one another;
a plurality of second connection terminals on a second region of the bottom surface of the interposer chip, wherein the plurality of second connection terminals electrically connect the interposer chip and the package substrate to one another;
a plurality of third connection terminals that electrically connect the interposer chip and the first semiconductor chip to one another; and
a plurality of fourth connection terminals that electrically connect the interposer chip and the second semiconductor chip to one another,
wherein a first width of the plurality of first connection terminals is a same as a third width of the plurality of third connection terminals,
wherein a second width of the plurality of second connection terminals is a same as a fourth width of the plurality of fourth connection terminals,
wherein the first region vertically overlaps the first semiconductor chip, and
wherein the second region vertically overlaps the second semiconductor chip.

13. The semiconductor package of claim 12, wherein:
an interval between the plurality of first connection terminals is a same as an interval between the plurality of third connection terminals, and
an interval between the plurality of second connection terminals is a same as an interval between the plurality of fourth connection terminals.

14. The semiconductor package of claim 12, wherein a top surface of the interposer chip comprises:
a third region on which the plurality of third connection terminals are provided; and
a fourth region on which the plurality of fourth connection terminals are provided,
wherein the first region vertically overlaps at least a portion of the third region, and
wherein the second region vertically overlaps at least a portion of the fourth region.

15. The semiconductor package of claim 14, wherein:
an arrangement of the plurality of first connection terminals is a same as an arrangement of the plurality of third connection terminals, and
the arrangement of the plurality of first connection terminals and the arrangement of the plurality of third connection terminals are shifted with respect to one another in a first direction parallel to the top surface of the interposer chip.

16. The semiconductor package of claim 12, wherein:
each of the plurality of third connection terminals is positioned above and overlaps a corresponding one of the plurality of first connection terminals, and
each of the plurality of fourth connection terminals is positioned above and overlaps a corresponding one of the second connection terminals.

17. The semiconductor package of claim 12, wherein:
the bottom surface of the interposer chip further comprises a third region that is an area other than the first region and the second region,
the interposer chip comprises a plurality of dummy terminals on the bottom surface of the interposer chip on the third region,
a fifth width of the plurality of dummy terminals is a same as the third width of the plurality of third connection terminals or the fourth width of the plurality of fourth connection terminals, and
an interval between the plurality of dummy terminals is a same as an interval between the plurality of third connection terminals or an interval between the plurality of fourth connection terminals.

18. The semiconductor package of claim 12, wherein the interposer chip further comprises:
a base layer;
a plurality of through vias that extend vertically in the base layer;
a plurality of lower pads on a bottom surface of the base layer, wherein the plurality of through vias are electrically coupled to the plurality of lower pads; and
a passive element on a top surface of the base layer.

19. The semiconductor package of claim 12, wherein:
the plurality of first connection terminals and the plurality of third connection terminals are electrically connected to the first semiconductor chip, and
the plurality of second connection terminals and the plurality of fourth connection terminals are electrically connected to the second semiconductor chip.

20. A semiconductor package, comprising:
a package substrate;
an interposer chip mounted on the package substrate through a plurality of dummy terminals, a plurality of first connection terminals, and a plurality of second connection terminals;
a semiconductor chip mounted on the interposer chip through a plurality of third connection terminals; and
a chip stack mounted on the interposer chip through a plurality of fourth connection terminals,
wherein the plurality of first connection terminals and the plurality of third connection terminals are electrically connected to the semiconductor chip,
wherein the plurality of second connection terminals and the plurality of fourth connection terminals are electrically connected to the chip stack,
wherein a width of the plurality of first connection terminals is a same as a width of the plurality of third connection terminals,
wherein a width of the plurality of second connection terminals is a same as a width of the plurality of fourth connection terminals,
wherein each of the plurality of third connection terminals is positioned above and overlaps a corresponding one of the plurality of first connection terminals,
wherein each of the plurality of fourth connection terminals is positioned above and overlaps a corresponding one of the plurality of second connection terminals, and
wherein the plurality of dummy terminals are between the plurality of first connection terminals and the plurality of third connection terminals and are electrically insulated from the semiconductor chip and the chip stack.
